(19) United States
(12) Patent Application Publication
(10) Pub. No.: US 2007/0134846 A1
(43) Pub. Date: Jun. 14, 2007

(54) Electronic member fabricating method and ic chip with adhesive material

(75) Inventors: Atsushi Takahashi, Tokyo (JP); Yoshihiro Ishida, Tokyo (JP)

Correspondence Address: OSHA LIANG L.L.P., 1221 MCKINNEY STREET, SUITE 2800, HOUSTON, TX, 77010, US

(73) Assignee: Nagase & Co. Ltd., Nishi-ku, Osaka-shi (JP)

(21) Appl. No.: 10/574,825

(22) PCT Filed: Oct. 7, 2004
(86) PCT No.: PCT/JP04/14865

§ 371 Date: Apr. 6, 2006

(30) Foreign Application Priority Data
Oct. 7, 2003 (JP) 2003-348318
Oct. 7, 2003 (JP) 2003-348319
Oct. 7, 2003 (JP) 2003-348320

(51) Int. Cl. H01L 21/58; H01L 23/12

(52) U.S. Cl. 438/113; 257/678; 257/684; 438/118; 438/464

(57) ABSTRACT

The present invention includes: an adhesive material attaching process for attaching a wafer to a thermoseffing adhesive material provided on a base film; a dicing-film attaching process for attaching the base film to a dicing film; an IC-chip separating process for cutting the wafer and the thermosetting adhesive material to divide them into IC chips; and a mounting process for attaching, to a carrier, the IC chips having the thermosetting adhesive material attached thereto; wherein the thermosetting adhesive material has a viscosity of 20000 Pa·s or less at the attaching temperature during the adhesive material attaching process.

### TECHNICAL FIELD

The present invention relates to a method for fabricating an electronic member by forming an adhesive-applied IC chip from a wafer and then fixing it to a carrier and relates to the IC chip with adhesive material.

### BACKGROUND ART

There is a conventional fabricating method which employs a wafer fixing member constituted by a thermosetting adhesive material, a dicing film and an ultraviolet curing adhesive placed therebetween (refer to, for example, Patent Document 1).

Hereinafter, with reference to FIG. 6, a conventional electronic member fabricating method will be described. In a wafer finishing process illustrated in FIG. 6(a), devices are formed in or on a wafer 1.

In a process for attaching an adhesive material including an ultraviolet curing adhesive illustrated in FIG. 6(b), a thermosetting adhesive material 8 is attached to the wafer 1. Thereafter, the thermosetting adhesive material 8 is semi-cured at 150° C. for 30 seconds, in order to enhance adhesion between the wafer 1 and the thermosetting adhesive material 8. An ultraviolet curing adhesive 9 and a dicing film 4 have been attached in advance to the opposite surface of the thermosetting adhesive material 8.

In a cutting process illustrated in FIG. 6(c), the wafer 1 and the thermosetting adhesive material 8 are cut along dicing lines on the wafer 1 with a dicing saw to divide them into IC chips 6 through dicing grooves 5.

In an ultraviolet radiation process illustrated in FIG. 6(d), an ultraviolet is irradiated to the ultraviolet curing adhesive 9 through the dicing film 4 to degrade the adhesion between the thermosetting adhesive material 8 and the ultraviolet curing adhesive 9.

In a mounting process illustrated in FIG. 6(e), the IC chip 6 having the thermosetting adhesive material 8 attached thereto is picked up and pressed to a carrier 7 at 150° C. for about 1 second to provisionally attach the IC chip 6 thereto, and thereafter it is cured at 180° C. for about 2 hours to make the IC chip 6 adhere to the carrier 7.

Also, there is a conventional IC chip with adhesive material including an ultraviolet curing adhesive-applied to a dicing film, which is provided by preparing a material made of a dicing film, an ultraviolet curing adhesive applied thereto and a thermosetting adhesive material attached to the ultraviolet curing adhesive, attaching the thermosetting adhesive material to a wafer, and then dicing them (refer to, for example, Patent Document 1). Further, as a thin IC chip, there is an IC chip with adhesive material including an ultraviolet curing adhesive-applied to a dicing film, which is provided by dicing a wafer in advance, back grinding a back surface of the wafer, preparing a material made of a dicing film, an ultraviolet curing adhesive applied thereto and a thermosetting adhesive material attached to the ultraviolet curing adhesive, attaching the thermosetting adhesive material to the previously diced wafer, and then dicing the wafer again (refer to, for example, Patent Document 2).

Hereinafter, with reference to FIGS. 7 and 8, conventional IC chips with adhesive material will be described. IC chips with adhesive material of FIG. 7 are fabricated as follows. A thermosetting adhesive material is attached to the back surface of a wafer which has gone through a front-end process for formation of semiconductor devices. A dicing film with an ultraviolet curing adhesive applied to the surface thereof is attached to the wafer with the thermosetting adhesive material attached thereto. Then, the wafer and the adhesive material are diced using a dicing saw to complete the fabrication. The ultraviolet curing adhesive 26 exists on the dicing film 24, and the thermosetting adhesive material 27 and IC chips 21, which are divided into IC-sized parts through separation grooves 25, are attached thereon. In a back-end process, an ultraviolet is irradiated thereto through the dicing film surface to degrade the adhesion of the ultraviolet curing adhesive 26. After that, the IC chips 21 attached with the thermosetting adhesive material 27 thereto are peeled-off and picked up at the interface between the thermosetting adhesive material 27 and the ultraviolet curing adhesive 26, because the adhesion at the interface has been degraded due to the picking up of the IC chips 21 from the IC-chip surfaces using vacuum tweezers or the like. Then, the IC chips 21 are transferred to a carrier such as a circuit board.

Adhesive-applied IC chips of FIG. 8 have a configuration which is proposed in order to overcome the problem that, when the wafer has a smaller thickness in FIG. 7 and a thermosetting adhesive material is attached to the wafer, the wafer is subject to significant warpage due to stresses of the thermosetting adhesive material, making it impossible to perform dicing thereto. Separation grooves are formed, with a dicing method, in a wafer which has gone through a front-end process for fabrication of semiconductor devices, wherein the separation grooves have a depth of 10 to 80% of a required wafer thickness from a back surface of the wafer. Thereafter, back grinding is applied to the back surface of the wafer to reduce the wafer thickness to the required thickness. Further, a material made of a dicing film: an ultraviolet curing adhesive applied to the surface of the dicing film and a thermosetting adhesive material attached thereon, is attached to the back surface of the wafer. Then, the wafer and the thermosetting adhesive material are diced with a width smaller than that of the aforementioned separation grooves, with a dicing saw, to complete the fabrication. The ultraviolet curing adhesive 26 exists on the dicing film 24, and the thermosetting adhesive material 27 and IC chips 21, which are divided into IC sized portions through second separation grooves 29, are attached thereon. The IC chips 21 are separated through the first separation grooves 28 and the second separation grooves 29, which have been formed in advance by dicing. In a back-end process, an ultraviolet is irradiated thereto through the dicing film surface to degrade the adhesion of the ultraviolet curing adhesive 26. After that, the IC chips 21 attached with the thermosetting adhesive material 27 thereto are peeled-off and picked up at the interface between the thermosetting adhesive material 27 and the ultraviolet curing adhesive 26, because the adhesion at the interface has been degraded due to the picking up of the IC chips 21 from the IC-chip surfaces using vacuum tweezers or the like. Then, the IC chips 21 are transferred to a carrier such as a circuit board.

Patent Document 1: Japanese Patent Application Laid-open No. Hei 2-248064

Patent Document 2: Japanese Patent Application Laid-open No. 2001-156028

### DISCLOSURE OF THE INVENTION

However, the aforementioned electronic member fabricating methods have the following problems. Namely, since an ultraviolet curing adhesive is interposed between a dicing film and a thermosetting adhesive material in order to enable certain and easy peeling of the thermosetting adhesive material from the dicing film after dicing, there have been problems such as higher cost and longer process time of the dicing film.

Furthermore, the aforementioned IC chips with adhesive material have the following problems. Namely, since a dicing film includes an ultraviolet curing adhesive applied thereon, there have been problems of higher cost and the like. Further, in cases of thin wafers, there have been problems of complexity of processes and the like.

The present invention has been made in consideration of the aforementioned problems of the prior art and its object is to provide electronic member fabricating methods which allow a lower cost and simpler processes, and an IC chip with adhesive material which allows a lower cost and simpler processes.

In order to attain the aforementioned object, a first electronic member fabricating method according to the present invention includes: an adhesive material attaching process for attaching a wafer to a thermosetting adhesive material provided on a base film; a dicing-film attaching process for attaching the base film to a dicing film; an IC-chip separating process for cutting the wafer and the thermosetting adhesive material to divide them into IC chips; and a mounting process for attaching, to a carrier, the IC chips having the thermosetting adhesive material attached thereto, wherein the thermosetting adhesive material has a viscosity of 20,000 Pa·s or less at the attaching temperature during the adhesive material attaching process.

Moreover, in order to attain the aforementioned object, a second electronic member fabricating method according to the present invention includes: an adhesive material attaching process for attaching a thermosetting adhesive material at least to a wafer; a dicing-film attaching process for attaching a dicing film to the thermosetting adhesive material; an IC-chip separating process for cutting the wafer and the thermosetting adhesive material to divide them into IC chips; and a mounting process for attaching, to a carrier, the IC chips having the thermosetting adhesive material attached thereto, wherein the thermosetting adhesive material has a viscosity of 20,000 Pa·s or less at the attaching temperature during the adhesive material attaching process.

Furthermore, in order to attain the aforementioned object, a third electronic member fabricating method according to the present invention includes: an adhesive material attaching process for attaching, at least to a wafer, a base film including a thermosetting adhesive material adhered thereon; a cutting process for cutting the wafer and the thermosetting adhesive material to divide them into IC chips by using the base film as a dicing film; and a mounting process for attaching, to a carrier, the IC chips having the thermosetting adhesive material attached thereto, wherein the thermosetting adhesive material has a viscosity of 20,000 Pa·s or less at the attaching temperature during the adhesive material attaching process.

According to the electronic member fabricating methods, since no expensive ultraviolet curing adhesive is employed, it is possible to provide a low-cost process, allowing fabrication from inexpensive materials and shortening of the processes.

Further, since the thermosetting adhesive material has a viscosity of 20,000 Pa·s or less during the attachment in the adhesive material attaching process, it is possible to promote an adhesion between the adhesive material and the wafer, thereby suppressing the occurrence of voids between the wafer and the thermosetting adhesive material.

In particular, according to the third electronic member fabricating method of the present invention, the base film which is a base material for the adhesive material also serves as a dicing film, which enables reduction in cost and waste generation.

In the aforementioned first to third electronic member fabricating methods, it is preferable that the thermosetting adhesive material have additionally a viscosity of 100 Pa·s or more at the attaching temperature during the adhesive material attaching process. This gives a favorable manageability of the adhesive material.

Furthermore, it is preferable that the thermosetting adhesive material do not start a heat curing reaction at the attaching temperature during the adhesive material attaching process.

It is also preferable that the attaching temperature during the adhesive material attaching process be lower than the temperature at which a heat curing of the thermosetting adhesive material starts.

In these cases, the adhesive material is not cured during the attachment. Accordingly, this can prevent a warpage and a stretch of the wafer due to stresses in the adhesive material, after the attachment, even when the wafer has a small thickness, and also can prevent the occurrence of burrs on the adhesive material during the cutting process. Particularly, this solves the following problem. When the thickness of the wafer is reduced in accordance with reduction of the package thickness, if the thermosetting adhesive material is semi-cured due to heat generated during the attachment of the thermosetting adhesive material and the subsequent heat curing, the wafer is subject to warpage due to stresses generated between the wafer and the thermosetting adhesive material, which may cause the problem such as a failure of dicing. Further, since the warpage and the stretch of the carrier caused by the temperature are negligible, reliable processes realizing high position accuracy can be provided.

Further, since the adhesive material is not cured during the adhesive material attaching process, the adhesion between the adhesive material and the carrier during the mounting process can be promoted, whereby voids can be further reduced.

It is also preferable that the thermosetting adhesive material have a viscosity of 20,000 Pa·s or less at the attaching temperature during the mounting process.

This can ensure sufficient adhesion between the adhesive material and the carrier, and suppress the occurrence of voids between the carrier and the adhesive material.

It is further preferable that the thermosetting adhesive material have a viscosity of 100 Pa·s or more at the attaching temperature during the mounting process.

This gives a favorable manageability of the adhesive material.

It is also preferable that the thermosetting adhesive material do not start the heat curing reaction at the attaching temperature during the mounting process. This can ensure sufficient adhesion between the adhesive material and the carrier during the mounting.

It is further preferable that the thermosetting adhesive material be of a film type or a paste type.

In this case, it is possible to easily manage the adhesive material, since the thermosetting adhesive material is of a film type or a paste type.

Further, it is preferable to utilize a dicing saw in the cutting process.

It is also possible to employ an inexpensive fabricating apparatus by using the dicing saw for separating the IC chips.

Further, in the second electronic member fabricating method according to the present invention, it is preferable that the thermosetting adhesive material be covered with a base film in advance.

Further, in the second electronic member fabricating method according to the present invention, the dicing-film attaching process preferably includes a process for peeling the base film and a process for attaching the dicing film to the thermosetting adhesive material.

In this case, since the base film is peeled in advance, it is possible to employ a material having no adhering function, as the dicing film.

In order to attain the aforementioned object, an IC chip with 5 adhesive material according to the present invention is an IC chip with adhesive material including an IC chip and an adhesive material attached to the back surface thereof, wherein the adhesive material is directly stuck on a base film or a dicing film; the adhesive material contains at least a thermosetting resin; the adhesive material has not started the curing reaction; and the adhesive material has a viscosity of 20,000 Pa·s or less at a temperature equal to or less than a reaction starting temperature.

According to an IC chip with adhesive material of the present invention, a low-cost IC chip with adhesive material can be provided: the adhesive material is directly stuck to the base film or the dicing film and therefore is inexpensive and easy to manage; and the adhesive material is made of a thermosetting resin to ensure adhesion with respect to the carrier.

Further, since the adhesive material has not started the curing reaction, the IC chip experiences less stresses and has a reliability preventing the occurrence of burrs during the dicing.

Furthermore, since the adhesive material has a viscosity of 20,000 Pa·s or less at a temperature equal to or less than the reaction starting temperature, it is possible to prevent the occurrence of voids between the adhesive material and the IC chip before the start of reaction, and to ensure adhesion between the IC chip and the adhesive material. It is also possible to prevent the occurrence of voids during the attachment to the carrier.

It is preferable that the adhesive material have a viscosity of 100 Pa·s or more at a temperature equal to or less than a curing-reaction starting temperature.

It is also preferable that the adhesive material start the curing reaction at a temperature in the range of 80 to 120° C.

In the case where the adhesive material starts the curing reaction at a temperature in the range of 80 to 120° C., when the IC chip with adhesive material is attached to the carrier at a temperature lower than the curing-reaction starting temperature, for example, at a temperature in the range of 70 to 90° C., the warpage and the stretch of the wafer are nearly negligible, whereby reliable processes realizing high position accuracy can be provided.

It is also preferable that the adhesive material be made of a film-type resin.

Since the adhesive material is of a film type, it is possible to easily manage the adhesive material during fabrication and also it is possible to easily prevent the rise of the adhesive material to the surface of the IC chip during adhesion to the carrier even when the thickness of the IC chip is small.

It is also preferable that the IC chip have a thickness of 200 micrometers or less.

Even when the IC chip has a thickness of 200 micrometers or less, it is possible to provide an effective configuration which facilitates fillet control, without causing warpage.

Further, when the adhesive material has substantially the same size (plain shape) as that of the IC chip, it is possible to easily perform fillet control.

According to the present invention, there are provided electronic member fabricating methods which allow a lower cost and simpler processes, and IC chips with an adhesive agent which allow a lower cost and simpler processes.

### BRIEF DESCRIPTION OF THE DRAWINGS

FIG. 1 is an explanatory view illustrating a wafer finishing process, an adhesive material attaching process, a dicing-film attaching process, an IC-chip separating process and a mounting process, in an electronic member fabricating method according to a first embodiment of the present invention.

FIG. 2 is an explanatory view illustrating a wafer finishing process, an adhesive material attaching process, a base-film attaching process, a dicing-film attaching process, an IC-chip separating process and a mounting process, in an electronic member fabricating method according to a second embodiment of the present invention.

FIG. 3 is an explanatory view illustrating a wafer finishing process, an adhesive material attaching process, an IC-chip separating process and a mounting process, in an electronic member fabricating method according to a third embodiment of the present invention.

FIG. 4 is an explanatory view illustrating an explanatory view of IC chips with adhesive material according to a fourth embodiment of the present invention.

FIG. 5 is an explanatory view illustrating an explanatory view of other IC chips with adhesive material according to a fifth embodiment of the present invention.

FIG. 6 is an explanatory view of a conventional electronic member fabricating method.

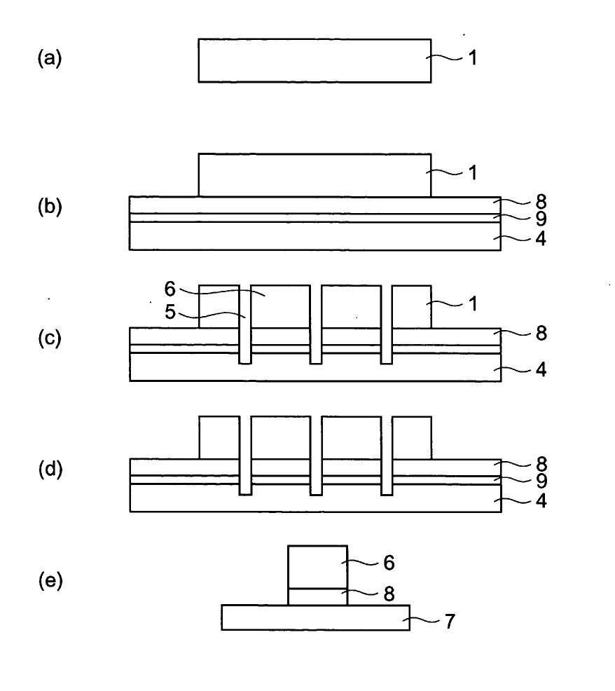

FIG. 7 is an explanatory view illustrating a cross-sectional view of conventional IC chips with adhesive material.

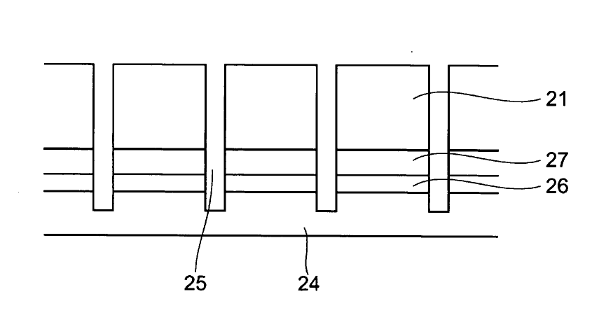

FIG. 8 is an explanatory view illustrating a cross-sectional view of the conventional IC chips with adhesive material.

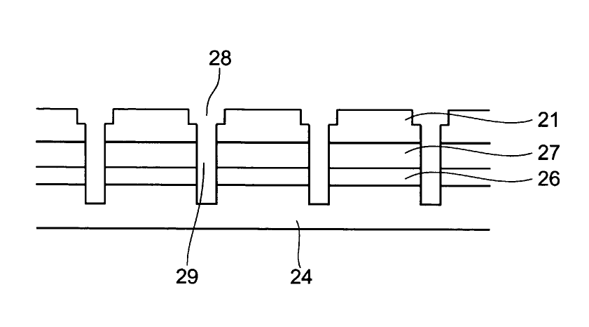

### DESCRIPTION OF REFERENCE SYMBOLS

1. wafer

2, 8. adhesive material

3. base film

4. dicing film

5. dicing grooves

6. IC chip

7. carrier

9. ultraviolet curing adhesive

21. IC chip

22, 27. adhesive material

23. base film

24. dicing film

25. separation grooves

26. ultraviolet curing adhesive

28. first separation grooves

29. second separation grooves

### BEST MODES FOR CARRYING OUT THE INVENTION

### FIRST AND SECOND EMBODIMENTS

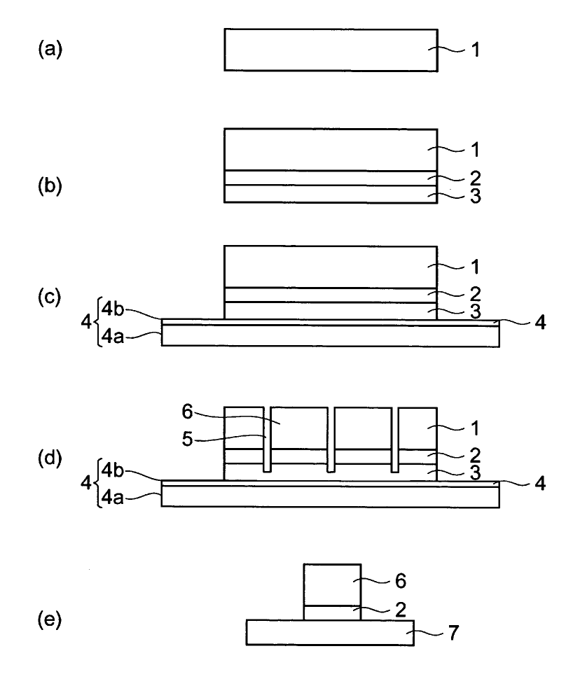

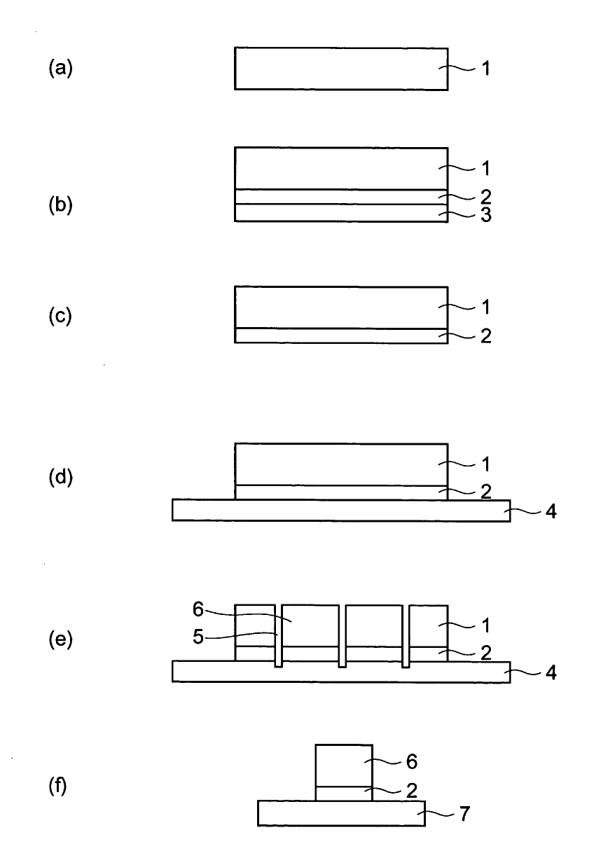

Hereinafter, on the basis of FIG. 1 and FIG. 2, one exemplary method for mounting an IC-chip according to the present invention will be described. FIG. 1 is an explanatory view illustrating a wafer finishing process, an adhesive material attaching process, a dicing-film attaching process, an IC-chip separating process and a mounting process, in an electronic member fabricating method according to a first embodiment of the present invention.

First, the wafer finishing process of FIG. 1(a) is the same as that of the prior art and description thereof is omitted herein.

In the adhesive material attaching process illustrated in FIG. 1(b), a film-type adhesive material 2 formed on a base film 3 is attached to a wafer 1 through a laminator. After the completion of the attachment, no provisional curing is performed.

As the base film, for example, a PET film or the like may be employed.

As the adhesive material, an adhesive material which has a viscosity of 20,000 Pa·s or less at the adhesive attaching temperature is employed. Further, in view of handling, it is preferable to employ an adhesive material which has a viscosity of 100 Pa·s or more at the adhesive attaching temperature.

It is preferable that the attaching temperature be a temperature which reduces the viscosity of the adhesive material to allow easy attachment, but does not cause heat curing of the adhesive material in order to prevent stresses from being applied to the wafer after the attachment.

For example, it is preferable that the specific attaching temperature be, when the temperature which starts the curing of the adhesive is about 80 to 120° C., lower than the curing-starting temperature and, for example, is a temperature in the range of 70 to 90° C. Such a relatively low temperature is less prone to induce stresses in the wafer and therefore is preferable.

Further, it does not matter that not just a film type adhesive but a paste type adhesive material may be directly applied to the wafer through a printing method or the like.

The specific material of the adhesive material may be an adhesive material of thermosetting type; an adhesive material mainly consisting of a thermosetting resin such as an epoxy resin, or a mixture of a thermosetting resin and a thermoplastic resin may be used. Further, the adhesive material may contain silica, silver or metal powders or the like as required, in addition to resin constituents, to exhibit an insulation characteristic, an electrical conductivity and an anisotropic electrical conductivity. Furthermore, the surface onto which the adhesive material is attached is not limited to the wafer back surface and may be the front surface of the wafer. Also, bumps may be formed in advance on the pad surface of the front surface.

More specifically, as the material for adhesive material satisfying the aforementioned characteristics, it is preferable to employ a film-type material containing an epoxy resin, a curing agent, an inorganic filler and polyether sulfone, wherein 100 parts by weight of the total sum of the epoxy resin, the curing agent and the polyether sulfone contains 5 to 900 parts by weight of the inorganic filler, and 100 parts by weight of the total sum of the epoxy resin and the curing agent contains 5 to 100 parts by weight of the polyether sulfone.

As an epoxy resin, it is possible to employ various types of conventionally known epoxy resins, such as bisphenol-A type epoxy resins, bisphenol-F type epoxy resins, phenol novolac type epoxy resins, cresol novolac type epoxy resins, bisphenol-AD type epoxy resins, biphenyl type epoxy resins, naphthalene type epoxy resins, alicyclic epoxy resins, glycidyl ester resins, glycidyl amine-type epoxy resins, heterocyclic epoxy resins, diallyl sulfone epoxy resins, hydroquinone epoxy resins, and their denatured materials. Particularly, it is preferable to employ crystalline epoxy resins which are solids at normal temperatures, since they have low melt viscosities.

The curing agent cures the epoxy resin when it is heated. It is possible to employ various types of conventionally known curing agents having activation temperatures or curing reaction starting temperatures in the range of 60 to 180° C. and, more preferably, in the range of 80 to 120° C. Such curing agents include dicyandiamide, its derivatives, organic acid hydrazide, amineimide, polyamine salt, microcapsule-type curing agents, imidazole latent curing agents, acid anhydrides, phenol novolac and the like. In the present embodiment, it is preferable to employ a capsule-type curing agent.

As the inorganic filler, it is possible to employ various types of conventionally known fillers such as silica, alumina, titania, aluminum hydroxide. However, particularly in view of flowability and low linear expansion coefficient, it is preferable to employ a spherical-shaped fused silica.

By employing the aforementioned materials, it is possible to preferably obtain an adhesive which is thermally cured at about 80 to 120° C. while having a viscosity of 20,000 Pa·s or less at un-cured states.

In order to form a film-type adhesive material 2 on a base film 3, a solvent may be added to the adhesive material 2 and then the adhesive material 2 containing the solvent may be applied to the base film 3 and dried thereon.

A release agent such as silicone may also be provided to the surface of the base film 3: the surface contacts with the adhesive material 2.

In the dicing-film attaching process illustrated in FIG. 1(c), a dicing film 4 is attached to the surface of the base film 3.

The dicing film 4 is constituted by a dicing substrate 4a and an adhesive 4a provided thereon, and the base film 3 is adhered to the adhesive 4b. It is not necessary that the adhesive 4a be of an ultraviolet curing type.

In the IC-chip separating process illustrated in FIG. 1(d), dicing grooves 5 are formed along dicing lines on the wafer 1 by using a dicing saw, such that at least the wafer 1 and the adhesive material 2 are divided into plural parts and also at least a portion of the base film 3 is left. Thus, IC-chips 6 are formed. Namely, the adhesive 2 is completely cut in accordance with the shapes of the IC chips.

In the mounting process illustrated in FIG. 1(e), an IC chip 6 having the adhesive material 2 adhered thereto is picked up and then is attached to a carrier 7 at a predetermined position. At this time, by peeling the adhesive material 2 from the base film 3, the IC chip 6 having the adhesive material 2 adhered thereto is picked up from the dicing film 4. The carrier 7 is not limited to a circuit board such as a ceramic board, a rigid board and a flexible board, and may be an IC chip.

With the aforementioned configuration, since an adhesive having a viscosity in the aforementioned range is employed and therefore the adhesive material has sufficient flowability during the adhesive material attaching process, the intimate contact between the wafer 1 and the adhesive material 2 can be improved, thereby suppressing the occurrence of voids in the adhesive material. Further, the adhesive material is not thermally cured at the temperature at which the adhesive material attaching process is performed, which can suppress stresses applied to the wafer during the process, thereby reducing the warpage of the wafer, in comparison with cases of curing or semi-curing the adhesive.

Further, since it is not necessary to employ an ultraviolet curing adhesive in the dicing film, it is possible to reduce the cost. Also, it is not necessary to apply UV irradiation.

Further, in the IC-chip separating process, due to the flowability of the adhesive material, it is possible to suppress the occurrence of burrs on the adhesive material divided into individual parts.

Further, since the adhesive material has certain flowability, the intimate contact between the adhesive material and the carrier can be improved prior to the heat curing, thereby suppressing the occurrence of voids on the adhesive material, in the mounting process.

Hereinafter, a second embodiment will be described.

FIG. 2 is an explanatory view illustrating a wafer finishing process, an adhesive material attaching process, a base-film peeling process, a dicing-film attaching process, an IC-chip separating process and a mounting process, in another electronic member fabricating method according to a second embodiment of the present invention. The same components as those in the prior art are designated by the same reference symbols.

The wafer finishing process of FIG. 2(a) is the same as that in the prior art and description thereof is omitted herein. The adhesive material attaching process of FIG. 2(b) is the same as the process of FIG. 1(b) and description thereof is omitted herein.

In the base-film peeling process illustrated in FIG. 2(c), a base film is peeled from an adhesive material 2.

In the dicing-film attaching process illustrated in FIG. 2(d), a dicing film 4 is directly attached to the surface of the adhesive material 2. No other adhesive is applied to the surfaces of the adhesive material 2 and the dicing film 4.

In the IC-chip separating process illustrated in FIG. 2(e), dicing grooves 5 are formed along dicing lines on a wafer 1 by using a dicing saw such that at least the wafer 1 and the adhesive 2 are divided into plural parts and also at least a portion of the dicing film 4 is left. Thus, IC-chips 6 are formed. Namely, the adhesive 2 is completely cut in conformance with the shapes of the IC chips.

In the mounting process illustrated in FIG. 2(f), an IC chip 6 having the adhesive material 2 adhered thereto is picked up and then is attached to a carrier 7 at a predetermined position. At this time, by peeling the adhesive material 2 from the dicing film 4, the IC chip 6 having the adhesive material 2 adhered thereto is picked up therefrom. The carrier 7 is not limited to a circuit board such as a ceramic board, a rigid board, and a flexible board, and may be an IC chip.

In the present embodiment, it is possible to offer the same effects and advantages as those of the first embodiment. Further, since the adhesive material 2 is directly adhered to the dicing film 4, it is possible to eliminate the necessity of providing adhesiveness to the surface of the dicing film 4.

Also, in the second embodiment, the adhesive material attaching process can be implemented by employing an adhesive sheet including no base film.

It is also possible to apply a release agent such as silicone to the surface of the base film 3 which is to come into contact with the adhesive material 2. It is also possible to apply a release agent such as silicone to the surface of the base film 4 which is to come into contact with the adhesive material 2.

Hereinafter, the present embodiment will be described in more detail, by exemplifying concrete examples.

### FIRST EXAMPLE

A material made of a PET film and an adhesive material with a thickness of 25 micrometers attached thereon was laminated on an 8-inch wafer with a thickness of 200 micrometers, at 80° C., with a pressure of 4 kgf (4×10⁵ Pa), wherein the adhesive material has a viscosity of 20000 Pa·s at 80° C. and also has a reaction starting temperature of 100° C. At this time, inspections were conducted for warpage of the wafer and voids between the wafer and the adhesive material (a microscope with a magnification of 50 times). There was observed no wafer warpage or void which would be problematic during the subsequent processes. Thereafter, it was laminated on a dicing film, and the wafer and the adhesive material were diced into squares having a chip size of 10-millimeter-square. At this time, inspections were conducted for burrs on the adhesive material and scatters of chips. There was found no problem in terms of burrs and chip scatters. Thereafter, IC chips were picked up from the surface and mounted onto a rigid board at 80° C. In the picking up, the adhesive material was successfully peeled from the PET film, and no problem was induced during the operation. Further, there was found no void generated between the rigid board and the IC chip, and also there was found no problem in terms of position accuracy.

### FIRST COMPARATIVE EXAMPLE

An adhesive material was laminated on a wafer and then it was diced and mounted under the same condition as that in the first example, wherein the adhesive material has a viscosity of 25000 Pa·s at 80° C. while the other physical properties thereof were the same as those of the adhesive material of the first example. After attaching it to the wafer, there was found no warpage, but some voids (a microscope with a magnification of 50 times) were generated. Inspections conducted after the dicing revealed that there were no problematic burrs and chip scatters. During the picking up performed thereafter, the problem of separation of a portion of the chip from the adhesive material was induced.

### SECOND COMPARATIVE EXAMPLE

An adhesive material was laminated on a wafer and then it was diced and mounted under the same condition as that in the first example, wherein the adhesive material has a viscosity of 30000 Pa·s at 80° C. while the other physical properties thereof were the same as those of the adhesive material of the first example. After attaching it to the wafer, there was found no warpage, but there was found the occurrence of many voids (a microscope with a magnification of 50 times). Inspections conducted after the dicing revealed that no burr was induced, but there was induced the problem of scatters of some chips during the dicing. During the picking up performed thereafter, the problem of separation of many chips from the adhesive materials was induced.

### THIRD COMPARATIVE EXAMPLE

An adhesive material with a thickness of 25 micrometers attached on a dicing film including an ultraviolet curing adhesive adhered thereon was laminated on an 8-inch wafer with a thickness of 200 micrometers, at 80° C., with a pressure of 4 kgf (4×10⁵ Pa) and then was provisionally cured at 150° C. for 30 seconds, wherein the adhesive material has a viscosity of 100000 Pa·s at 80° C. and also has a reaction starting temperature of 70° C. Thereafter, the wafer and the adhesive material were diced into squares having a chip size of 10-millimeter-square. Then, an ultraviolet ray is irradiated thereto through the dicing film surface for 10 seconds, and then IC chips were picked up from the surface and mounted onto a rigid board at 150° C. After the attachment to the wafer and the provisional curing, warpage was generated. No void was generated (a microscope with a magnification of 50 times). Inspections conducted after the dicing revealed that many burrs were generated on the adhesive material. The problem of chip scatters during the dicing was not induced. No problem was induced during the subsequent picking up.

### THIRD EMBODIMENT

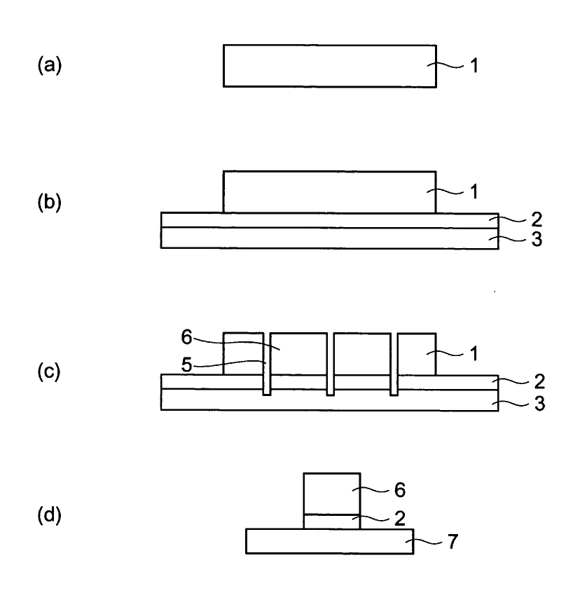

Hereinafter, on the basis of FIG. 3, an IC-chip mounting method according to a third embodiment of the present invention will be described. FIG. 3 is an explanatory view illustrating a wafer finishing process, an adhesive material attaching process, an IC-chip separating process and a mounting process, in an electronic member fabricating method according to the third embodiment of the present invention. The same components as those in the prior art are designated by the same reference symbols.

First, the wafer finishing process of FIG. 3(a) is the same as that in the prior art and description thereof is omitted herein.

In the adhesive material attaching process illustrated in FIG. 3(b), a film-type adhesive material 2 which has been formed in advance on a base film 3 is attached to a wafer 1 through a laminator, wherein the base film 3 also serves as a dicing film. After the completion of the attachment, no provisional curing is performed. It is preferable that the attaching temperature be a temperature which reduces the viscosity of the adhesive material to a value which facilitates the attachment, but does not cause heat curing of the adhesive material, in order to prevent stresses from being applied to the wafer after the attachment. For example, when the adhesive starts heat curing at a temperature in the range of about 80 to 120° C., a preferable attaching temperature which is less prone to induce stresses in the wafer is a temperature lower than the heat-curing starting temperature and, more specifically, a temperature in the range of about 70 to 90° C. In this case, an adhesive material which has a viscosity of 20000 Pa·s or less at the attaching temperature is employed. Further, it does not matter that a paste-type adhesive material may be formed in advance on a base film through a printing method or the like, instead of a film-type adhesive.

The material of the adhesive material may be any thermosetting adhesive material and may be, for example, an adhesive material mainly consisting of a thermosetting resin such as an epoxy resin or a mixture of a thermosetting resin and a thermoplastic resin. Further, the adhesive material may contain silica, silver, metal particles or the like as required, in addition to resin constituents, to exhibit an insulation characteristic, an electrical conductivity and an anisotropic electrical conductivity. Further, the surface onto which the adhesive material is attached is not limited to the back surface of the wafer and may be the front surface of the wafer. Also, bumps may be formed in advance on the pad surface of the front surface. In other words, the adhesive material 2 is the same. as that in the first embodiment and also the attaching temperature is the same as that in the first embodiment.

In the IC-chip separating process illustrated in FIG. 3(c), dicing grooves 5 are formed along dicing lines on the wafer 1 by using a dicing saw, such that at least the wafer 1 and the adhesive material 2 are divided into plural parts and also at least a portion of the base film 3 is left. Thus, IC-chips 6 are formed. Namely, the base film 3 functions as a dicing film. At this time, the adhesive 2 is completely cut in conformance with the shapes of the IC chips.

In the mounting process illustrated in FIG. 3(d), an IC chip 6 having the adhesive material 2 adhered thereto is picked up and then is attached to a carrier 7 at a predetermined position. At this time, by peeling the adhesive material 2 from the base film 3, the IC chip 6 having the adhesive material 2 adhered thereto is picked up. The carrier 7 is not limited to a circuit board such as a ceramic board, a rigid board, and a flexible board, and may be an IC chip.

In the present embodiment, it is possible to offer the same effects and advantages as those in the first embodiment. Further, the base film 3 which is the supporting base material for the adhesive material 2 serves as a dicing film, namely a film which secures the IC chips without being completely cut during the cutting process, thereby offering the advantages of cost reduction and waste reduction.

It is also possible to apply a release agent such as silicone to the surface of the base film 3 which is to come into contact with the adhesive material 2.

Hereinafter, the present embodiment will be described in more detail, by exemplifying concrete examples.

### FIRST EXAMPLE

A material made of a PET film and an adhesive material with a thickness of 25 micrometers attached thereon was laminated on an 8-inch wafer with a thickness of 200 micrometers, at 80° C., with a pressure of 4 kgf (4×10⁵ Pa), wherein the adhesive material has a viscosity of 20000 Pa·s at 80° C. and also has a reaction starting temperature of 100° C. At this time, inspections were conducted for warpage of the wafer and voids between the wafer and the adhesive material (a microscope with a magnification of 50 times). There was observed no wafer warpage or void which would be problematic during the subsequent processes. Thereafter, the wafer and the adhesive material were diced into squares having a chip size of 10-millimeter-square. At this time, inspections were conducted for burrs on the adhesive material and scatters of chips. There was found no problem in terms of burrs and chip scatters. Thereafter, IC chips were picked up from the surface and mounted onto a rigid board at 80° C. In the picking up, the adhesive material was successfully peeled from the dicing film, and no problem was induced during the operation. Further, there was found no void generated between the rigid board and the IC chip, and also there was found no problem in terms of position accuracy.

### FIRST COMPARATIVE EXAMPLE

An adhesive material was laminated on a wafer and then it was diced and mounted under the same condition as that in the first example, wherein the adhesive material has a viscosity of 25000 Pa·s at 80° C. while the other physical properties thereof were the same as those of the adhesive material of the first example. After attaching it to the wafer, there was found no warpage, but some voids (a microscope with a magnification of 50 times) were generated. Inspections conducted after the dicing revealed that there were no problematic burrs and chip scatters. During the picking up performed thereafter, the problem of separation of a portion of the chip from the adhesive material was induced.

### SECOND COMPARATIVE EXAMPLE

An adhesive material was laminated on a wafer and then it was diced and mounted under the same condition as that in the first example, wherein the adhesive material has a viscosity of 30000 Pa·s at 80° C. while the other physical properties thereof were the same as those of the adhesive material of the first example. After attaching it to the wafer, there was found no warpage, but there was found the occurrence of many voids (a microscope with a magnification of 50 times). Inspections conducted after the dicing revealed that no burr was induced, but there was induced the problem of scatters of some chips during the dicing. During the picking up performed thereafter, the problem of separation of many chips from the adhesive materials was induced.

### THIRD COMPARATIVE EXAMPLE

An adhesive material with a thickness of 25 micrometers attached on a dicing film including an ultraviolet curing adhesive adhered thereon was laminated on an 8-inch wafer with a thickness of 200 micrometers, at 80° C., with a pressure of 4 kgf (4×10⁵ Pa) and then was provisionally cured at 150° C. for 30 seconds, wherein the adhesive material has a viscosity of 100000 Pa·s at 80° C. and also has a reaction starting temperature of 70° C. Thereafter, the wafer and the adhesive material were diced into squares having a chip size of 10-millimeter-square. Then, an ultraviolet ray is irradiated thereto through the dicing film surface for 10 seconds, and then IC chips were picked up from the surface and mounted onto a rigid board at 150° C. After the attachment to the wafer and the provisional curing, warpage was generated. No void was generated (a microscope with a magnification of 50 times). Inspections conducted after the dicing revealed that many burrs were generated on the adhesive material. The problem of chip scatters during the dicing was not induced. No problem was induced during the subsequent picking up.

### FOURTH AND FIFTH EMBODIMENTS

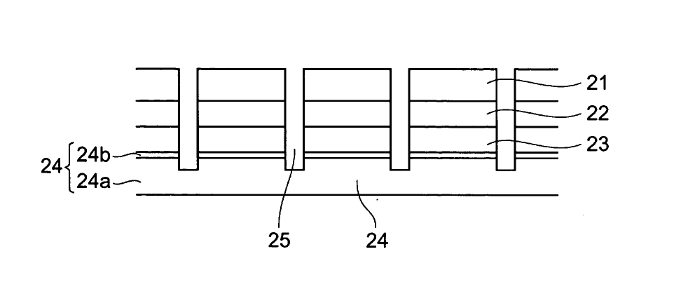

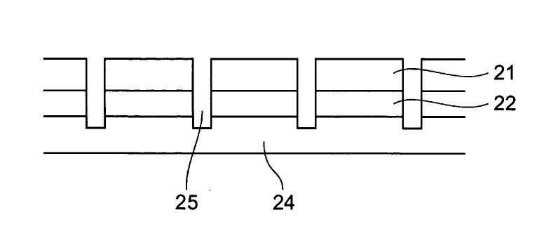

Hereinafter, on the basis of the drawings, an IC-chip mounting method according to the present invention will be described. FIG. 4 is a cross-sectional view of adhesive material-attached IC chips according to a fourth embodiment of the present invention. FIG. 5 is a cross-sectional view of another-adhesive material-attached IC chips according to a fifth embodiment of the present invention. The same components as those in the prior art are designated by the same reference symbols.

FIG. 4 illustrates adhesive material-attached IC chips which are fabricated by attaching, to a wafer, a material made of a base film and an adhesive material directly attached thereon, then attaching the base film to a dicing film and dicing them. A base film 23 is adhered to a dicing film 24, an adhesive material 22 is directly adhered to the base film 23 and IC chips 21 are adhered thereon. The IC chips 21 and the adhesive materials 22 are separated from the adjacent IC chips and adhesive materials through separation grooves 25. The adhesive materials 22 have substantially the same size as that of the IC chips 21 and, since the adhesive materials have not been cured, no warpage has been generated in the IC chips.

The adhesive materials 22 are the same as the adhesive materials 2 in the first embodiment.

The dicing film 24 is constituted by a dicing substrate 24a and an adhesive 24a provided thereon, and the base film 23 is adhered to the adhesive 24b. It is not necessary that the adhesive 4a be of an ultraviolet curing type.

The aspect of these adhesive-applied IC chips is the same as the adhesive-applied IC chips at the state illustrated in FIG. 1(d) in the first embodiment.

FIG. 5 illustrates a configuration in which a base film also serves as a dicing film. A material made of a dicing film (base film) and an adhesive material directly attached thereon is attached to a wafer and then they are diced to create adhesive-applied IC chips. The adhesive material 22 is directly adhered to the dicing film 24, and IC chips 21 are adhered thereon. The IC chips 21 and the adhesive materials 22 are separated from the adjacent IC chips and adhesive materials through separation grooves 25. The adhesive materials 22 have substantially the same size as that of the IC chips 21 and, since the adhesive materials have not been cured, no warpage has been generated in the IC chips.

The aspect of these adhesive-applied IC chips is the same as the adhesive-applied IC chips at the state illustrated in FIG. 2(e) in the second embodiment and the adhesive-applied IC chips at the state illustrated in FIG. 3(c) in the third embodiment.

With the adhesive-applied IC chips according to the present embodiment, the adhesive material is directly attached to the base film or the dicing film and, therefore, the adhesive material is inexpensive and easy to handle. Further, the adhesive materials have substantially the same size as that of the IC chips, which makes it easy to perform fillet control. Further, the adhesive materials are made of a thermosetting resin, which ensures adhesion with respect to the carrier and enables provision of low-cost adhesive-applied IC chips. Further, the adhesive materials have not started curing, which can suppress stresses applied to the IC chips, thereby preventing the occurrence of burrs during dicing and thus providing reliability.

Further, since the adhesive material has a viscosity of 20000 Pa·s or less at temperatures equal to or less than the reaction starting temperature, it is possible to prevent the occurrence of voids between the adhesive material and the IC chips prior to the start of thermal reaction, thereby ensuring the adhesion between the IC chips and the adhesive material. Further, it is also possible to prevent the occurrence of voids during attaching it to a carrier. In this case, it is preferable that the adhesive material have a viscosity of 100 Pa·s or more.

It is preferable that the adhesive material start heat curing at a temperature in the range of 80 to 120° C.

In the case where the adhesive material starts heat curing at a temperature in the range of 80 to 120° C., when the adhesive-applied IC chips are attached to a carrier at a temperature lower than the heat-curing starting temperature, the attaching temperature can be set to, for example, 70 to 90° C. and, in this case, the warpage and the stretch of the wafer caused by the temperature can be made negligible, thereby enabling provision of reliable processes which can realize high position accuracy.

When the adhesive material is made of a film-type resin, the adhesive material is easy to handle during fabrication and also it is possible to easily prevent the rise of the adhesive to the IC-chip surfaces during adhesion to the carrier even when the thickness of the IC chips is small.

Further, with the present embodiment, even when the IC chips has a thickness of 200 micrometers or less, no warpage is generated and also it is possible to easily perform fillet control.

Hereinafter, the present embodiment will be described in more detail, by exemplifying concrete examples.

### FIRST EXAMPLE

A material made of a PET film and an adhesive material with a thickness of 25 micrometers attached thereon was laminated on an 8-inch wafer with a thickness of 200 micrometers, at 80° C., with a pressure of 4 kgf (4×10⁵ Pa), wherein the adhesive material has a viscosity of 20000 Pa·s at 80° C. and also has a reaction starting temperature of 100° C. At this time, inspections were conducted for warpage of the wafer and voids between the wafer and the adhesive material (a microscope with a magnification of 50 times). There was observed no wafer warpage or void which would be problematic during the subsequent processes. Thereafter, it was laminated on a dicing film, and the wafer and the adhesive material were diced into squares having a chip size of 10-millimeter-square. At this time, inspections were conducted for burrs on the adhesive material and scatters of chips. There was found no problem in terms of burrs and chip scatters. Thereafter, IC chips were picked up from the surface and mounted onto a rigid board at 80° C. In the picking up, the adhesive material was successfully peeled from the PET film, and no problem was induced during the operation. Further, there was found no void generated between the rigid board and the IC chip, and also there was found no problem in terms of position accuracy. Then, the adhesive material was cured at 150° C. for one hour.

### FIRST COMPARATIVE EXAMPLE

An adhesive material was laminated on a wafer and then it was diced and mounted under the same condition as that in the first example, wherein the adhesive material has a viscosity of 25000 Pa·s at 80° C. while the other physical properties thereof were the same as those of the adhesive material of the first example. After attaching it to the wafer, there was found no warpage, but there was found the occurrence of many voids (a microscope with a magnification of 50 times). Inspections conducted after the dicing revealed that no burr was induced, but there was induced the problem of scatters of some chips during the dicing. During the picking up performed thereafter, the problem of separation of many chips from the adhesive materials was induced.

### SECOND COMPARATIVE EXAMPLE

An adhesive material with a thickness of 25 micrometers attached on a dicing film including an ultraviolet curing adhesive adhered thereon was laminated on an 8-inch wafer with a thickness of 200 micrometers, at 80° C., with a pressure of 4 kgf (4×10⁵ Pa) and then was provisionally cured at 150° C. for 30 seconds, wherein the adhesive material has a viscosity of 100000 Pa·s at 80° C. and also has a reaction starting temperature of 70° C. Thereafter, the wafer and the adhesive material were diced into squares having a chip size of 10-millimeter-square. Then, an ultraviolet ray is irradiated thereto through the dicing film surface for 10 seconds, and then IC chips were picked up from the surface and mounted onto a rigid board at 150° C. After the attachment to the wafer and the provisional curing, warpage was generated. No void was generated (a microscope with a magnification of 50 times). Inspections conducted after the dicing revealed that many burrs were generated on the adhesive material. The problem of chip scatters during the dicing was not induced. No problem was induced during the subsequent picking up.

1. An electronic member fabricating method comprising:
an adhesive material attaching process for attaching a wafer to a thermosetting adhesive material provided on a base film;
a dicing-film attaching process for attaching the base film to a dicing film;
an IC-chip separating process for cutting the wafer and the thermosetting adhesive material to divide them into IC chips; and
a mounting process for attaching, to a carrier, the IC chips having the thermosetting adhesive material attached thereto;
wherein the thermosetting adhesive material has a viscosity of 20000 Pa·s or less at the attaching temperature during the adhesive material attaching process.

2. An electronic member fabricating method comprising:
an adhesive material attaching process for attaching a thermosetting adhesive material at least to a wafer;
a dicing-film attaching process for attaching a dicing film to the thermosetting adhesive material;
an IC-chip separating process for cutting the wafer and the thermosetting adhesive material to divide them into IC chips; and
a mounting process for attaching, to a carrier, the IC chips having the thermosetting adhesive material attached thereto;
wherein the thermosetting adhesive material has a viscosity of 20000 Pa·s or less at the attaching temperature during the adhesive material attaching process.

3. The electronic member fabricating method according to claim 2, wherein the thermosetting adhesive material is covered with a base film in advance.

4. The electronic member fabricating method according to claim 3, wherein the dicing-film attaching process includes a process for peeling the base film and a process for attaching the dicing film to the thermosetting adhesive material.

5. An electronic member fabricating method comprising:
an adhesive material attaching process for attaching, at least to a wafer, a base film including a thermosetting adhesive material adhered thereon;
a cutting process for cutting the wafer and the thermosetting adhesive material to divide them into IC chips by using the base film as a dicing film; and
a mounting process for attaching, to a carrier, the IC chips having the thermosetting adhesive material attached thereto;
wherein the thermosetting adhesive material has a viscosity of 20000 Pa·s or less at the attaching temperature during the adhesive material attaching process.

6. The electronic member fabricating method according to claims claim 1, wherein the thermosetting adhesive material has a viscosity of 100 Pa·s or more at the attaching temperature during the adhesive material attaching process.

7. The electronic member fabricating method according to claim 1, wherein the thermosetting adhesive material does not start the heat curing reaction at the attaching temperature during the adhesive material attaching process.

8. The electronic member fabricating method according to claim 1, wherein the attaching temperature during the adhesive material attaching process is lower than the temperature that starts heat curing of the thermosetting adhesive material.

9. The electronic member fabricating method according to claim 1, wherein the thermosetting adhesive material has a viscosity of 20000 Pa·s or less at the attaching temperature during the mounting process.

10. The electronic member fabricating method according to claim 9, wherein the thermosetting adhesive material has a viscosity of 100 Pa·s or more at the attaching temperature during the mounting process.

11. The electronic member fabricating method according to claim 1, wherein the thermosetting adhesive material does not start the heat curing reaction at the attaching temperature during the mounting process.

12. The electronic member fabricating method according to claim 1, further comprises a process for heating the thermosetting adhesive material to cause the heat curing reaction, after the mounting process.

13. The electronic member fabricating method according to claim 1, wherein the thermosetting adhesive material is of a film type or a paste type.

14. The electronic member fabricating method according to claim 1, wherein a dicing saw is used in the cutting process.

15. An adhesive-applied IC chip including an IC chip and an adhesive material adhered to the back surface of the IC chip, wherein the adhesive material is directly attached on a base film or a dicing film, the adhesive material contains at least a thermosetting resin, the adhesive material has not started the curing reaction and the adhesive material has a viscosity of 20000 Pa·s or less at temperatures equal to or less than the curing-reaction starting temperature.

16. The adhesive-applied IC chip according to claim 15, wherein the adhesive material has a viscosity of 100 Pa·s or more at temperatures equal to or less than the curing-reaction starting temperature.

17. The adhesive-applied IC chip according to claim 15, wherein the adhesive material starts the curing reaction at a temperature in the range of 80 to 120° C.

18. The adhesive-applied IC chip according to claim 15, wherein the adhesive material is a film-type resin.

19. The adhesive-applied IC chip according to claim 15, wherein the IC chip has a thickness of 200 micrometers or less.

20. The adhesive-applied IC chip according to claim 15, wherein the adhesive material has substantially the same size as that of the IC chip.

21. The electronic member fabricating method according to claim 2, wherein the thermosetting adhesive material has a viscosity of 100 Pa·s or more at the attaching temperature during the adhesive material attaching process.

22. The electronic member fabricating method according to claim 5, wherein the thermosetting adhesive material has a viscosity of 100 Pa·s or more at the attaching temperature during the adhesive material attaching process.

23. The electronic member fabricating method according to claim 2, wherein the thermosetting adhesive material does not start the heat curing reaction at the attaching temperature during the adhesive material attaching process.

24. The electronic member fabricating method according to claim 5, wherein the thermosetting adhesive material does not start the heat curing reaction at the attaching temperature during the adhesive material attaching process.

25. The electronic member fabricating method according to claim 2, wherein the attaching temperature during the adhesive material attaching process is lower than the temperature that starts heat curing of the thermosetting adhesive material.

26. The electronic member fabricating method according to claim 5, wherein the attaching temperature during the adhesive material attaching process is lower than the temperature that starts heat curing of the thermosetting adhesive material.

27. The electronic member fabricating method according to claim 2, wherein the thermosetting adhesive material has a viscosity of 20000 Pa·s or less at the attaching temperature during the mounting process.

28. The electronic member fabricating method according to claim 5, wherein the thermosetting adhesive material has a viscosity of 20000 Pa·s or less at the attaching temperature during the mounting process.

29. The electronic member fabricating method according to claim 27, wherein the thermosetting adhesive material has a viscosity of 100 Pa·s or more at the attaching temperature during the mounting process.

30. The electronic member fabricating method according to claim 28, wherein the thermosetting adhesive material has a viscosity of 100 Pa·s or more at the attaching temperature during the mounting process.

31. The electronic member fabricating method according to claim 2, wherein the thermosetting adhesive material does not start the heat curing reaction at the attaching temperature during the mounting process.

32. The electronic member fabricating method according to claim 5, wherein the thermosetting adhesive material does not start the heat curing reaction at the attaching temperature during the mounting process.

33. The electronic member fabricating method according to claim 2, further comprises a process for heating the thermosetting adhesive material to cause the heat curing reaction, after the mounting process.

34. The electronic member fabricating method according to claim 5, further comprises a process for heating the thermosetting adhesive material to cause the heat curing reaction, after the mounting process.

35. The electronic member fabricating method according to claim 2, wherein the thermosetting adhesive material is of a film type or a paste type.

36. The electronic member fabricating method according to claim 5, wherein the thermosetting adhesive material is of a film type or a paste type.

37. The electronic member fabricating method according to claim 2, wherein a dicing saw is used in the cutting process.

38. The electronic member fabricating method according to claim 5, wherein a dicing saw is used in the cutting process.
